(19) United States
(12) Patent Application Publication
(10) Pub. No.: US 2013/0181242 A1
(43) Pub. Date: Jul. 18, 2013

(54) ORGANIC ELECTROLUMINESCENT DEVICE AND METHOD FOR MANUFACTURING THEREOF

(71) Applicant: Doo-Hee CHO, Daejeon (KR)

(72) Inventor: Doo-Hee CHO, Daejeon (KR)

(73) Assignee: ELECTRONICS AND TELECOMMUNICATIONS RESEARCH INSTITUTE, Daejeon (KR)

(21) Appl. No.: 13/359,443

(22) Filed: Jan. 26, 2012

(30) Foreign Application Priority Data
Jan. 18, 2012 (KR) 10-2012-0005744

(51) Int. Cl. H01L 51/52; H01L 51/56; B82Y 99/00

(52) U.S. Cl. 257/98; 438/29; 257/E51.026; 977/952

(57) ABSTRACT

Disclosed is an organic electroluminescent device and a method for manufacturing thereof, the device including a light emitting part in which a substrate, a first electrode, an organic light emitting layer and a second electrode, and a nano structure including a first opening part randomly distributed between the substrate and the first electrode, wherein the nano structure includes at least anyone of polyimide, epoxy, polycarbonate, PVC, PVP, polyethylene, polyacryl and perylene, each having a refractive index in the range of 1.3˜1.5, whereby a light extraction can be improved by restricting a reflective light from an interface between the substrate and the first electrode.

Pursuant to 35 U.S.C. §119 (a), this application claims the benefit of earlier filing date and right of priority to Korean Patent Application No. 10-2012-0005744, filed on Jan. 18, 2012, the contents of which is hereby incorporated by reference in their entirety.

### BACKGROUND OF THE DISCLOSURE

1. Field

The teachings in accordance with the exemplary embodiments of this present disclosure generally relate to an organic electroluminescent device and a method for manufacturing thereof, and more particularly to an organic electroluminescent device including a nano embossing structure configured to induce a light extraction of an organic electroluminescent device, and a method for manufacturing thereof.

2. Background

Organic electroluminescent devices, for example, organic electroluminescent diodes, are provided with a thin film containing a light-emitting organic compound between an anode and a cathode. By injecting holes and electrons from the respective electrodes, excitons of the light-emitting organic compound are generated. When these excitons return to a ground state, the organic electroluminescent devices irradiate light.

That is, the organic electroluminescent device is a device, wherein holes and electrons respectively injected from a plurality of opposing electrodes are combined within a light-emitting layer that employs an organic substance, thereby generating an energy that excites a fluorescent substance within the light-emitting layer, causing the device to emit light.

Recent developments in organic electroluminescent devices have been very significant. Characteristic examples of such developments include high brightness at low applied voltages, more diversity in emission wavelengths, wide viewing angle, rapid response, and the ability to produce thinner and lighter light-emitting devices. As a result of these developments, a broad range of possible applications are being suggested for organic electroluminescent devices. In this regard, the organic electroluminescent device is a self light-emitting type display device that emits light by electrically exciting a fluorescent organic compound.

A full color spectrum in the organic electroluminescent device is realized by having pixels that respectively emit red (R), green (G), and blue (B) colors, or white color.

According to M. E. Thompson et al, external light extraction efficiency in the organic electroluminescent devices may be expressed by an inner energy efficiency multiplied by light extraction efficiency. In the organic electroluminescent display of prior art, the light generated by the light-emitting layer inside each organic electroluminescent device is guided in the substrate and the organic semiconductor layer in the direction (horizontal direction) in which that layer extends, at a percentage of approximately 80%. As a result, the organic electroluminescent device of prior art has a light extraction efficiency in the frontal direction of the organic display of only approximately 20%, in general, resulting in poor light extraction efficiency and difficulties in increasing luminance. That is, the electric field light emission efficiency rate with respect to added energy is about 20%.

Light confined and guided in each layer of the organic electroluminescent device is called a guided mode light, and light emitted to outside air through an interface of each layer is called an emitted mode light. At this time, the guided mode light is converted to emitted mode light on a panel-type surface light source device, and emitted to an outside of the device, where this process is called a light extraction.

In the case of utilizing emission from an excited singlet, since a generation ratio of a singlet exciton to a triplet exciton is 1/3, that is, a generation probability of an emitting exciton species is 25% and a light taking out efficiency is approximately 20%, the limit of an external quantum efficiency of taking out light is said to be 5%.

Further, to obtain high emission efficiency, material of same refractive index or of high refractive index must be stacked toward an emission direction in the organic electroluminescent device. However, it is problematic that a transparent substrate, e.g., a glass substrate, used for light emission has a low refractive index of 1.5.

FIG. 1 is a schematic view illustrating a stacked structure of an organic electroluminescent device according to prior art, where the device includes a substrate (10), an anode (20) which is a transparent electrode, an organic light emitting layer (30), a cathode (40) which is a reflective electrode and a protective film (50) in that order.

In the organic electroluminescent device according to prior art, most of the light emitted to the cathode among the light generated from an organic light emitting layer is reflected to direct to the anode, and therefore most of the generated light is emitted to the anode after all. At this time, in the organic electroluminescent device where anode is stacked on the substrate, a glass substrate having transparency is used for the substrate in order to emit light.

In the course of the light being emitted to air through an organic light emitting layer, an anode and a substrate, a reflective light \textcircled{1} between the organic light emitting layer and an anode layer, a reflective light \textcircled{2} between the anode layer and the substrate and a reflective light \textcircled{3} between the substrate and the air are generated.

Particularly, light incident on an interface from a low density medium to high density medium at an angle more than a critical angle relative to verticality of a substrate surface is all reflected according to the following Snell's Law (Equation 1), whereby the light is not emitted to outside and disappears inside the device.

$$\frac{{n}_{1}}{{n}_{2}} = \frac{sin {a}_{2}}{sin {a}_{1}} \qquad [ Equation 1 ]$$

where,
n₁ is a refractive index of material before incidence,
n₂ is a refractive index of material after incidence,
a₁ is an incident angle relative to perpendicular to plane of incidence,
and a₂ is a refractive angle relative to perpendicular to plane of incidence.

Visible light refractive index of organic light emitting layer in the organic electroluminescent diode varies depending on wavelength of light, and is generally in the range of 1.6˜1.9. A refractive index of ITO (Indium Tin Oxide) that is used for anode is generally in the range of 1.9˜2.0, such that there is no problem because total reflection between the organic light emitting layer and the anode is almost nil.

However, in case a refractive index of generally-used glass or plastic transparent substrate is approximately 1.5, and thickness of an organic light emitting layer in the organic electroluminescent diode and an anode layer is generally very thin, in the range of 100˜400 nm, whereby most of the light generated from the organic light emitting layer cannot be emitted to outside due to being in a guided mode. That is, the internal light is not emitted from the transparent or semi-transparent substrate to the outside but remains inside.

This is because most of the light generated from the organic light emitting layer is incident on a substrate of low refractive index at an angle not perpendicular to substrate surface but almost parallel to the substrate surface.

Thus, the rate of light \textcircled{4} emitted from glass substrate in the conventional organic electroluminescent diode with respect to total emission is about 20%, which is very low.

As noted from the Equation 1, if refractive indexes of materials at both sides of interface are same, an incident angle and refractive angle become same to prevent generation of total reflection. That is, if refractive indexes of the organic light emitting layer and the anode, and those of the substrate are same or similar, generation of guided mode by total reflection at the interface between the substrate and anode is minimized to enhance the light extraction efficiency and to increase power efficiency of the organic electroluminescent diode.

However, because the refractive index of ITO used for anode is generally in the range of 1.9˜2.0, it is very difficult to find a material for substrate having same refractive index as that of anode. Furthermore, light is generally emitted toward the anode in the organic electroluminescent diode, it is very rare to find a material for substrate that is transparent, high in transmittance at a visible light range, has a refractive index of 1.9˜2.0, an adequate strength and surface smoothness. Even if the material is available, it is very difficult to manufacture a substrate, using the material that is thin like a sheet glass, flat, smooth and in a large surface scale.

### SUMMARY OF THE INVENTION

The present disclosure has been made to solve the foregoing disadvantages of the prior art, and therefore an object of certain embodiments of the present disclosure is to provide an organic electroluminescent device including a nano embossed structure configured to induce a light extraction of an organic electroluminescent device, and a method for manufacturing thereof.

Technical subjects to be solved by the present disclosure are not restricted to the above-mentioned description, and any other technical problems not mentioned so far will be clearly appreciated from the following description by the skilled in the art. That is, the present disclosure will be understood more easily and other objects, characteristics, details and advantages thereof will become more apparent in the course of the following explanatory description, which is given, without intending to imply any limitation of the disclosure, with reference to the attached drawings.

An object of the invention is to solve at least one or more of the above problems and/or disadvantages in whole or in part and to provide at least advantages described hereinafter. In order to achieve at least the above objects, in whole or in part, and in accordance with the purposes of the disclosure, as embodied and broadly described, and in one general aspect of the present disclosure, there is provided an organic electroluminescent device, the device comprising: a light emitting part in which a substrate, a first electrode, an organic light emitting layer and a second electrode are stacked; and a nano structure including a first opening part randomly distributed between the substrate and the first electrode.

Meanwhile, in another general aspect of the present disclosure, there is provided an organic electroluminescent device, the device comprising: a light emitting part in which a substrate, a first electrode, an organic light emitting layer and a second electrode are stacked; and a nano pattern part including a second opening part randomly formed on a stacked surface of the substrate on which the first electrode is stacked.

Meanwhile, in still another general aspect of the present disclosure, there is provided an organic electroluminescent device, the device comprising: a light emitting part in which a substrate, a first electrode, an organic light emitting layer and a second electrode are stacked; a nano structure including a first opening part randomly distributed between the substrate and the first electrode; and a nano pattern part including a second opening part randomly formed on a stacked surface of the substrate on which the first electrode is stacked.

Preferably, but not necessarily, the nano structure is less than 10% in visible light absorptance.

Preferably, but not necessarily, the nano structure includes at least any one of polyimide, epoxy, polycarbonate, PVC, PVP, polyethylene, polyacryl and perylene, each having a refractive index in the range of 1.3˜1.5.

Preferably, but not necessarily, width of a convex part formed at the nano pattern part or width of the nano structure is in the range of 100 nm˜1000 nm, and a gap between each convex part or a gap between each nano structure is in the range of 100 nm˜3000 nm.

Preferably, but not necessarily, the organic electroluminescent device further comprises a planarizing layer stacked to cover the nano structure or the nano pattern part, wherein the planarizing layer includes at least one of inorganic matter, polymer and a composite of the inorganic matter and the polymer, each having a refractive index in the range of 1.3˜1.5, wherein the inorganic matter includes at least any one of TiO2, TiO2-SiO2, ZrO2, ZnS, SnO2 and In2O3, and wherein the polymer includes at least any one of polyvinyl, phenol resin, epoxy resin, polyimide resin, polystyrene resin, polycarbonate resin, polyethylene resin, PMMA resin, polypropylene resin and silicone resin.

Preferably, but not necessarily, an external light extraction part is formed at a surface opposite to the stacked surface of the substrate on which the first electrode is stacked.

In still another general aspect of the present disclosure, there is provided a method for manufacturing an organic electroluminescent device, the method comprising: forming a nano structure or a nano pattern part between a substrate and a first electrode by masking a metal film formed by dewetting in an organic electroluminescent device on which a substrate, a first electrode, an organic light emitting layer and a second electrode.

To be more specific, a method for manufacturing an organic electroluminescent device comprises: coating an organic layer on a substrate; depositing a metal film on the organic layer; obtaining a pattern in which a first portion, where a metal formed with the metal film by heating the substrate is collected by dewetting, and a second portion exposed by the organic layer, are mixed in a randomly shape; exposing the substrate by etching the second portion; and removing the metal film.

Meanwhile, in still further general aspect of the present disclosure, there is provided a method for manufacturing an organic electroluminescent device, the method comprising: coating an organic layer on a substrate; depositing a metal film on the organic layer; obtaining a pattern in which a first portion, where a metal formed with the metal film by heating the substrate is collected by dewetting, and a second portion exposed by the organic layer, are mixed in a randomly shape; exposing the substrate by etching the second portion; and removing the metal film.

Meanwhile, in still further general aspect of the present disclosure, there is provided a method for manufacturing an organic electroluminescent device, the method comprising: coating an organic layer on a substrate; depositing a metal film on the organic layer; obtaining a pattern in which a first portion, where a metal formed with the metal film by heating the substrate is collected by dewetting, and a second portion exposed by the organic layer, are mixed in a randomly shape; exposing the substrate by etching the second portion; and removing the metal film.

At this time, preferably, but not necessarily, a temperature heating the substrate is in the range of 200° C.˜400° C.

Preferably, but not necessarily, width of the first portion is in the range of 100 nm˜1000 nm, and a distance to the first portion is in the range of 100 nm˜3000 nm.

Preferably, but not necessarily, the metal film includes at least any one of Ag, Au, Cu, Pt, Ni, Cr, Pd, Mg, Pb and Mo.

Preferably, but not necessarily, thickness of the metal film is in the range of 5 nm˜100 nm.

Preferably, but not necessarily, thickness of the organic layer is in the range of 50 nm˜1000 nm.

Preferably, but not necessarily, the method includes forming a planarizing layer having a thickness in the range of 100 nm˜2000 nm, a visible light absorptance of less than 10% and a surface roughness Ra of less than 10 nm.

Preferably, but not necessarily, the method includes forming on the substrate at least any one of an MLA (Micro-lens Array) layer, a fine embossed pattern layer, and an antireflective coating layer.

The organic electroluminescent device and the method for manufacturing thereof according to the present disclosure have an advantageous effect in that the device includes a nano embossed structure randomly interposed between a substrate and a first electrode stacked on the substrate and a nano pattern part, whereby a light extraction can be improved by restricting a reflective light from an interface between the substrate and the first electrode.

Another advantageous effect is that the nano structure is randomly generated by using dewetting phenomenon of metal to simplify a manufacturing process.

Still another advantageous effect is that a refractive index, height, width gap can be adjusted as desired if a nano structure of organic layer is applied, thereby enabling to obtain a reliable light extraction.

As a result, an organic electroluminescent device improved of light extraction efficiency can be provided with less manufacturing cost.

### BRIEF DESCRIPTION OF THE DRAWINGS

The accompanying drawings, which are included to provide a further understanding of the disclosure and are incorporated in and constitute apart of this application, illustrate embodiment(s) of the disclosure, and together with the description serve to explain the principle of the disclosure. In the drawings:

FIG. 1 is a schematic view illustrating a stacked structure of an organic electroluminescent device according to prior art;

FIG. 2 is a schematic view illustrating an organic electroluminescent device according to the present disclosure;

FIG. 3 is a schematic view illustrating a structure of phosphorescent white OLED (Organic Light Emitting Diode) having two light emitting layers;

FIG. 4 is a schematic view illustrating an operation principle of a hybrid white OLED of triplet harvesting type;

FIG. 5 is a schematic view illustrating a structure of a hybrid white OLED (WOLED) of direct recombination type;

FIG. 6 is a schematic view illustrating a light extraction principle of an MLA (Microlens Array);

FIG. 7 is a schematic view illustrating a light extraction principle of micro resonance using Bragg mirror;

FIG. 8 is a schematic view illustrating an organic electroluminescent device according to an exemplary embodiment of the present disclosure;

FIG. 9 is a schematic view illustrating a photograph of a metal pattern formed by dewetting phenomenon using an electron microscope;

FIG. 10 is a schematic view illustrating an organic electroluminescent device according to another exemplary embodiment of the present disclosure;

FIG. 11 is a schematic view illustrating an organic electroluminescent device according to still another exemplary embodiment of the present disclosure;

FIG. 12 is a schematic view illustrating a process of manufacturing an organic electroluminescent device according to the present disclosure;

FIG. 13 is a schematic view illustrating another process of manufacturing an organic electroluminescent device according to the present disclosure;

FIG. 14 is a schematic view illustrating still another process of manufacturing an organic electroluminescent device according to the present disclosure; and

FIG. 15 is a schematic view illustrating thickness and height of nano structure and smooth layer and a distance between the nano structure and smooth layer.

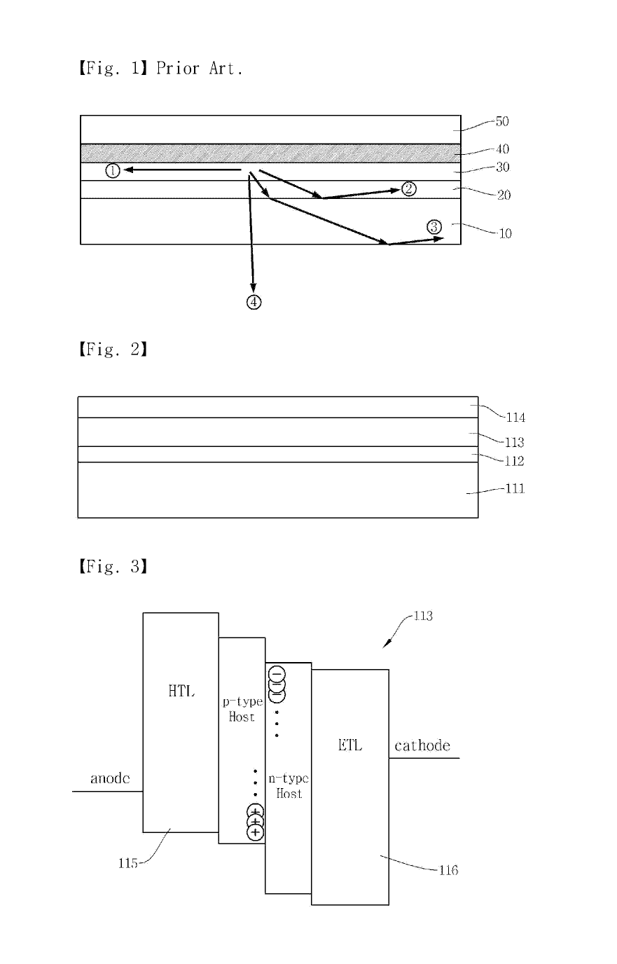

### DETAILED DESCRIPTION

Various exemplary embodiments will be described more fully hereinafter with reference to the accompanying drawings, in which some exemplary embodiments are shown. The present inventive concept may, however, be embodied in many different forms and should not be construed as limited to the example embodiments set forth herein. Rather, these exemplary embodiments are provided so that this description will be thorough and complete, and will fully convey the scope of the present inventive concept to those skilled in the art.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Furthermore, “exemplary” is merely meant to mean an example, rather than the best. It is also to be appreciated that features, layers and/or elements depicted herein are illustrated with particular dimensions and/or orientations relative to one another for purposes of simplicity and ease of understanding, and that the actual dimensions and/or orientations may differ substantially from that illustrated. Descriptions of well-known components and processing techniques are omitted so as not to unnecessarily obscure the embodiments of the disclosure.

Hereinafter, an organic electroluminescent device and method for manufacturing thereof according to the present disclosure will be described in detail with reference to the accompanying drawings.

FIG. 2 is a schematic view illustrating an organic electroluminescent device according to the present disclosure.

The organic electroluminescent device in FIG. 2 includes a stacked layer of a substrate (111), a first electrode (112), an organic light emitting layer (113) and a second electrode (114) in that order.

The substrate (111) serves to provide a mechanical strength to the organic electroluminescent device and functions as a transparent window at the same time. The substrate may be glass or plastic configured to pass light, where the plastic may be PET (Polyethylene Terephthalate), PC (Polycarbonate), PES (Polyethersulfone) and PI (Polyimide).

The first electrode (112) may be an anode or a cathode. For convenience of explanation, it is assumed that the first electrode (112) is an anode and a transparent electrode of ITO (Indium Tin Oxide). The second electrode (114) has a polarity corresponding to that of the first electrode (112). For example, in a case the first electrode (112) is an anode, the second electrode (114) is a cathode, and in a case the first electrode (112) is a cathode, the second electrode (114) is an anode.

The organic light emitting layer (113) is a factor generating light in response to power provided from the first and second electrodes (112, 114) and includes an organic matter. For example, the organic electroluminescent device (OLED) is a self light-emitting type display device that emits light by electrically exciting a fluorescent organic compound, using a principle in which energy is emitted when electrons and holes are recombined at the organic light emitting layer (113) when an electric field is applied, and light of particular wavelength is generated.

A basic structure of organic electroluminescent device (OLED) includes, in an order close to the substrate (111), an anode (ITO), a hole injection layer, a hole transport layer, a light emitting layer, an electron transport layer, an electron injection layer and a cathode (metal electrode). At this time, layers positioned between the first and second electrodes (112, 114), to be specific, the hole injection layer, the hole transport layer, the light emitting layer, the electron transport layer and the electron injection layer are called an organic light emitting layer.

The organic light emitting layer may be categorized into three types, based on used material, that is, a fluorescent, a phosphorescent and a hybrid white OLED.

The organic light emitting layer using the fluorescent material may be excellent in terms of device stability, but limited in harvesting high efficiency. The organic light emitting layer using the phosphorescent material may be excellent in harvesting high efficiency, but limited in harvesting a stable blue material. In an effort to compensate the problems of the two materials, a hybrid method is being briskly waged to use the fluorescent material for blue color and the phosphorescent material for other colors.

Referring to FIG. 3 illustrating a structure of phosphorescent white OLED (Organic Light Emitting Diode) having two light emitting layers, the structure includes two light emitting layers (113), in addition to a hole injection/transport layer (115), an electron injection/transport layer (116). At this time, the light emitting layer includes a p-type host material and an n-type host material, where each host material is formed with HOMO/LUMO (Highest Occupied/Lowest Unoccupied Molecular Orbitals) structure having high hole injection and electron injection barriers.

The hybrid white OLED is a device replacing blue color with fluorescent material that provides a big problem in stability in phosphorescent white OLED. The hybrid white OLED may be divided into two types, that is, a triplet harvesting type configured to use a triplet fluorescent layer, and a direct recombination type.

First, the triplet harvesting type is a very attractive method in that theoretically all currents can be used as light energy.

The principle by the triplet harvesting type is, as shown in FIG. 4 illustrating an operation principle of a hybrid white OLED of triplet harvesting type, most of the recombination occurs at the fluorescent layer comprising the light emitting layer, whereby a blue light emission can be harvested by a singlet exciton of fluorescent layer. A triplet exciton that is not used in recombination zone of fluorescent layer moves to a phosphorescent layer by energy diffusive transfer to harvest green and red phosphorescent light emissions. Based on this principle, 25% of singlet is converted to a fluorescent layer of blue light emission, while balance of 75% of triplet is converted to a phosphorescent layer of green/red light emission to harvest 100% of conversion efficiency. That is, this line of principle would set a new benchmark for the theoretical efficiency limit, namely 75% for triplet emission as opposed to the 25% for singlet emission.

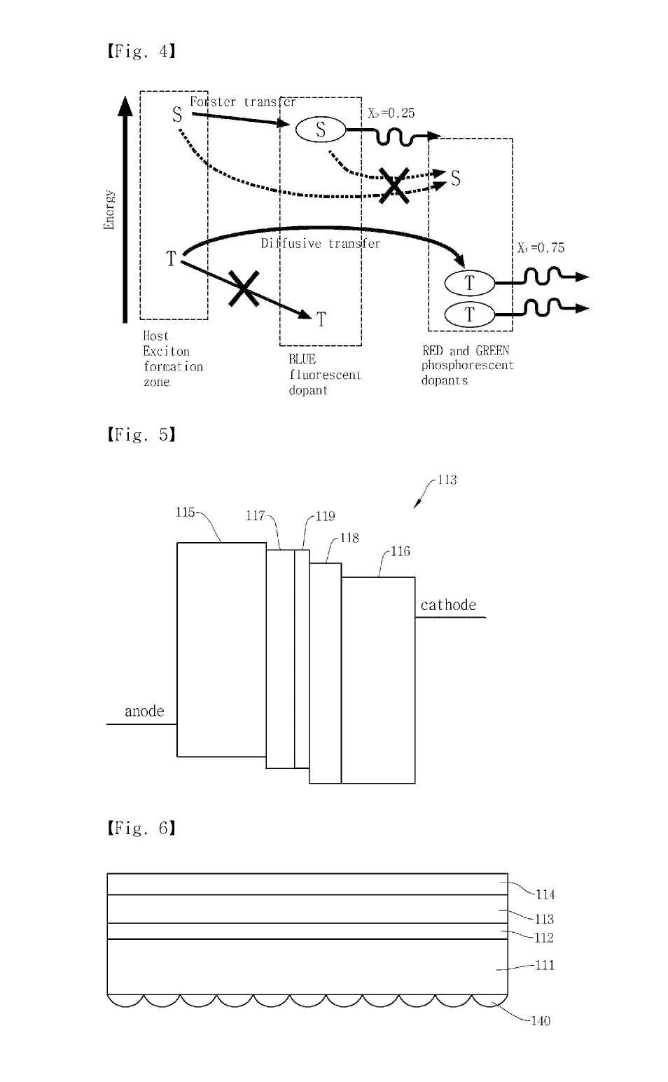

A structure of direct recombination type hybrid white OLED, as shown in FIG. 5 illustrating a structure of a hybrid white OLED (WOLED) of direct recombination type, is such that the recombination zone can be formed both at a fluorescent layer (117) and a phosphorescent layer (118), whereby light emission can be harvested from both the fluorescent layer and the phosphorescent layer.

As noted from the foregoing, another problem that has to be coped with in the OLED is a light extraction problem.

A refractive index of organic light emitting layer is 1.6˜1.9, and that of ITO generally used for anode is approximately 1.9˜2.0. A total thickness of two layers is very thin, that is, approximately 100˜400 nm. A refractive index of glass widely used for a substrate is approximately 1.5, such that a planar waveguide is spontaneously formed inside the OLED. Based on a calculation, ratio of light loss by inner waveguide mode due to the abovementioned reasons is known to reach approximately 45%.

Furthermore, being that a refractive index of substrate is approximately 1.5, and that of outside air is approximately 1.0, light incident at an angle more than a critical angle when the light is emitted to the outside remains inside due to total reflection, where ratio of light that remains inside is approximately 35%, such that only approximately 20% of light is emitted to the outside.

Therefore, a light extraction technology is a core factor increasing efficiency, luminescence and life of an OLED illumination panel because of low external light efficiency of OLED resultant from low light extraction efficiency.

A technique to extract light isolated in organic light emitting/ITO layer by difference of refractive index between anode (ITO) and substrate is an internal light extraction, and a technique to extract light isolated inside the substrate to outside (air) is called an external light extraction technology.

Improvement of realistic light efficiency using the external light extraction technique is only 1.6 times, such that generation of color change caused by diffraction based on viewing angle must be minimized. The external light extraction technology may include formation of an MLA (Multi-lens Array) layer, an external light scattering layer and antireflective film, for example.

Although theoretically, the internal light extraction technique can enhance light extraction efficiency three times or more, there is a disadvantage of very sensitively affecting an interface of inner OLED, such that it would be more advisable to satisfy all the electrical, chemical and mechanical properties in addition to optical effect. The internal light extraction technique may include inner light scattering layer, substrate surface deformation, refractive index adjusting layer, photonic crystal and nano structure forming methods, for example.

The MLA in the external light extraction is such that small lenses each having a diameter smaller than 1 mm are two-dimensionally arrayed on a surface opposite to air on a planar surface. The external light extraction employs a principle based on the light extraction principle of MLA, as depicted in FIG. 6 illustrating a light extraction principle of an MLA (Micro-lens Array), in which light is not entrapped inside the substrate by total reflection to allow light to be emitted, because incident angle of light relative to a surface tangent line of a micro-lens (140) is smaller than a critical angle.

In the external light extraction, an external light scattering layer may be manufactured in a sheet format using a method similar to that of micro-lens array sheet, and attached to outside of the substrate, and alternatively may be manufactured in solution type, coated on the substrate and hardened for use.

The antireflective film in the external light extraction is such that dielectric materials are thinly stacked in 1 to 3 layers on a cross-section of an optical device in order to remove light reflection generated by sudden changes in refractive index on the cross-section of optical device and to increase quantum of passing light.

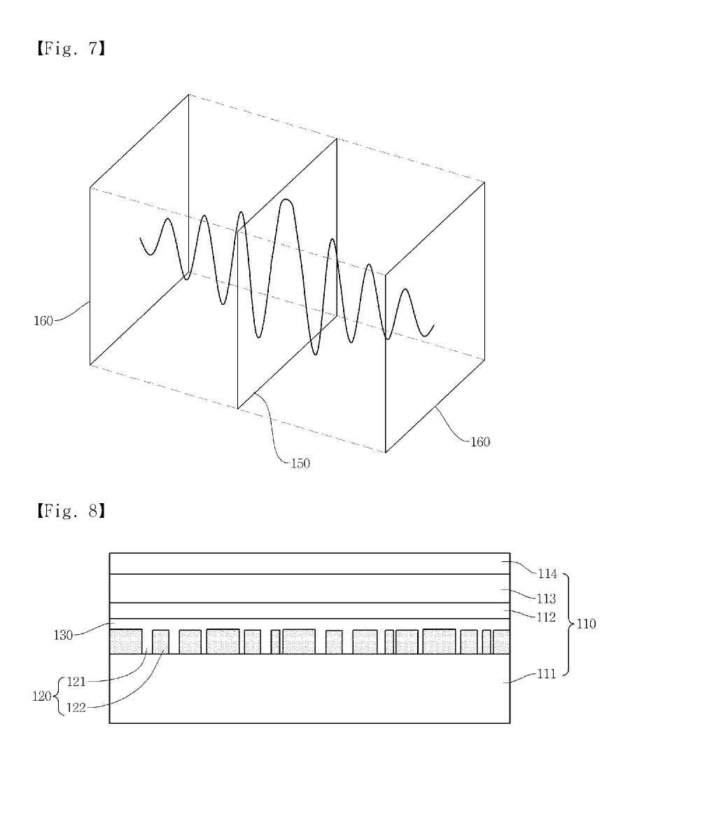

A micro-resonator in the internal light extraction is also called a micro-cavity, and generates a resonance with a spacer layer (150) in the middle and Bragg mirrors (160) or metal mirror layers at both sides, as shown in FIG. 7 illustrating a light extraction principle of micro resonance using Bragg mirror. If thickness of cathode surpasses λ/4 relative to light wavelength λ, the light extraction efficiency deteriorates so that it is preferred that the thickness of cathode be less than λ/4.

A structure of a photonic crystal in internal light extraction is such that dielectric constant-different two materials are aligned in nano meter scale at a predetermined period, whereby transmission is permitted or restricted in response to light wavelength to allow light of a particular wavelength to be reflected or to pass.

The internal scattering layer in the internal light extraction is advantageous in that, as explained in the external scattering layer, brightness of pattern is uniform, because of no color change in response to viewing angle and fundamentally a full scattering surface (Lambertian reflectance function or Lambertian radiation characteristics). Furthermore, the scattering layer can be relatively easily manufactured because it is sufficient that heterogeneous materials be well mixed and coated on a glass substrate. In order to use the scattering layer in a structure for the internal light extraction, thickness thereof must be thinly manufactured so that visible light absorbency is less than 0.1.

The nano embossing structure in the internal light extraction is a light extraction structure using only advantages of photonic crystal and external scattering layer. The photonic crystal may be used only in a particular light wavelength and cannot be disadvantageously used in white OLED. The external scattering layer has a disadvantage in that the light extraction efficiency is halved due to difficulty in overcoming the internal absorption. The nano embossing structure has no predetermined period and an irregular structure alignment, although an embossing structure of several hundred nano meters is used in the internal light extraction structure as in the external scattering layer. The nano embossing structure thus explained has a partial diffraction effect and acts as a single-tier scattering layer. Thus, dependency on light wavelength, color changes in response to viewing angle and distortion of light distribution become almost non-existent, and self-absorption is almost negligible.

Now, light extraction measure using the nano embossing structure will be described in detail with reference to accompanying figures.

FIG. 8 is a schematic view illustrating an organic electroluminescent device according to an exemplary embodiment of the present disclosure. The organic electroluminescent device of FIG. 8 may include a light emitting part (110) in which a substrate (111), a first electrode (112), an organic light emitting layer (113) and a second electrode (114) are stacked, and a nano structure including a first opening part (121) randomly distributed between the substrate (111) and the first electrode (112).

The substrate (111), the first electrode (112), the organic light emitting layer (113) and the second electrode (114) are stacked in that order. At this time, an additional layer may be interposed between each layer that performs an additional function. The first electrode may be a transparent anode, and the second electrode may be a reflective cathode. The anode and cathode may be changed in positions thereof in opposite way according to methods for manufacturing the organic electroluminescent device.

The structure (120) corresponding to the nano embossing structure explained before is distributed between the substrate (111) and the first electrode (112). The nano structure (120) has one or more first opening parts (121) when viewed from a plan view, and a convex part (122) and a concave part when viewed from a cross-sectional view.

The convex part (122) corresponds to the first opening part (121) and is a groove or a hole to be exact. If the first opening part is a hole, an additional layer on a substrate positioned underneath the nano structure or on the substrate is exposed as much as the hole. If the first opening part is a groove, the additional layer on the substrate or the substrate is not exposed.

The first opening part is randomly distributed between the substrate (111) and the first electrode (112), such that it can be viewed that an entire nano structure including the first opening is randomly distributed.

The nano structure (120) randomly distributed between the substrate and the first electrode is formed by metal dewetting phenomenon and dry etching method such as reactive ion etching. Alternatively, the metal dewetting phenomenon, dry etching and wet etching methods may be simultaneously utilized.

That is, an organic layer is coated on a substrate such as organic substrate or an additional layer stacked a substrate, and a metal layer is coated on the organic layer. Thereafter, the dewetting phenomenon of metal layer is induced using a heat treatment to manufacture several score to several hundred nano meter-sized metal patterns. The metal patterns thus manufactured function as etching masks for etching of organic layers. Successively, an organic layer underneath the metal pattern remains after reactive ion etching using oxygen plasma, and other portions are etched to make the organic layer possess same pattern as the metal pattern. If the metal pattern is removed using nitric acid while leaving the organic pattern, a nano structure with the organic layer is formed on the substrate.

The metal pattern may take various shapes by adjusting thickness and material of metal layer, heat treating temperature and time, ambience, and material and surface treatment of organic layer. That is, the metal pattern may take an air bubble-collected shape, a shape of metal film centrally formed with a small hole, and an irregularly weaved moire shape by adjusting the aforementioned environments.

FIG. 9 is a schematic view illustrating a photograph of a metal pattern formed by dewetting phenomenon using an electron microscope.

First, resin containing polyimide is coated on a soda-lime organic substrate in a 500 nm thickness. An Ag—Pd alloy of 50 nm is deposited thereon, and heated in a vacuum oven for about 10 minutes under 300° C., a result of which is shown in a plane view by FIG. 9 illustrating a photograph using an electron microscope. It can be noted that the metallic Ag—Pd alloy forms convex portions (172) in response to dewetting phenomenon, and openings (171) having relatively no alloy are randomly distributed.

That is, convex portions (122) of nano structure are formed on metallic convex portions (172), and first openings (121) of nano structure are formed on metallic openings (171). To be more specific, a metal pattern (125) formed by dewetting phenomenon is used as mask to easily manufacture a nano structure (120) having the first opening (121).

The nano structure having randomly distributed first openings function as a scattering layer. Thus, dependency on light wavelength, color changes in response to viewing angle and distortion of light distribution become almost non-existent, and self-absorption is almost negligible through the random distribution.

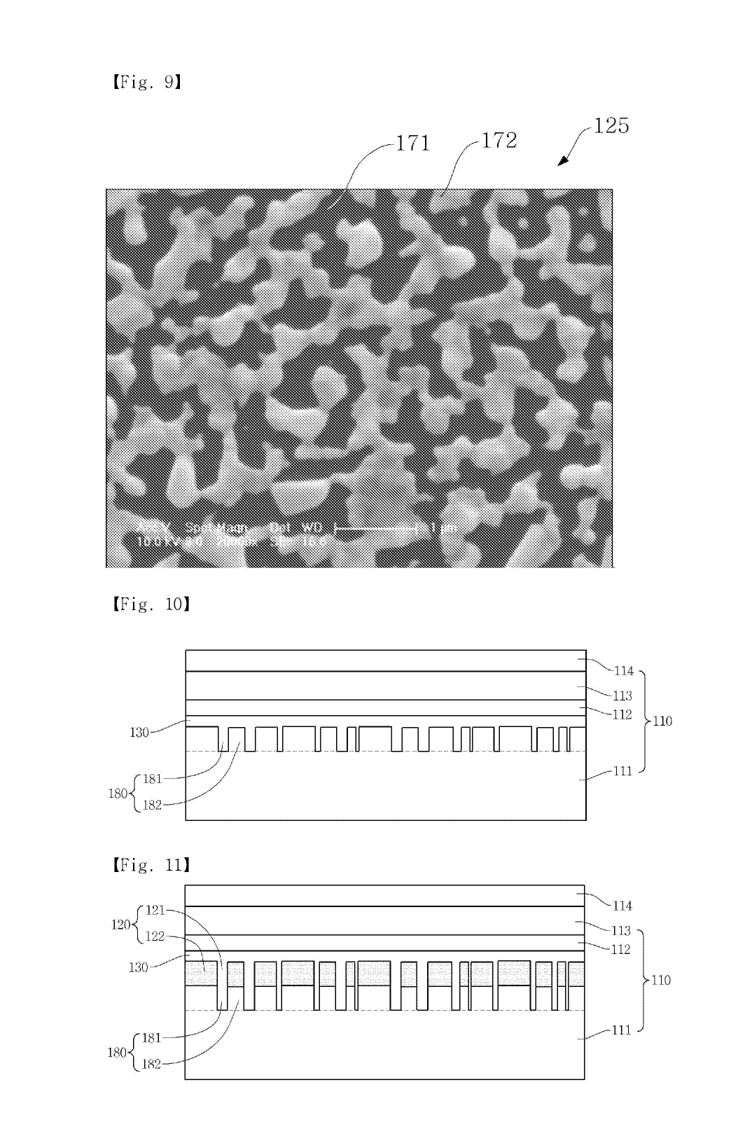

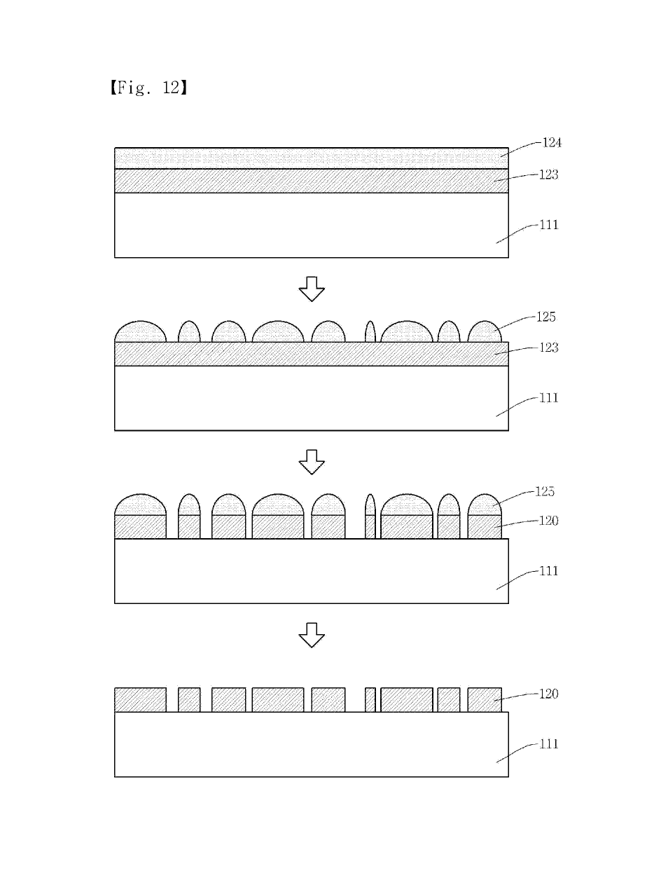

FIG. 10 is a schematic view illustrating an organic electroluminescent device according to another exemplary embodiment of the present disclosure.

The organic electroluminescent device of FIG. 10 may include a light emitting part (110) in which a substrate (111), a first electrode (112), an organic light emitting layer (113) and a second electrode (114) are stacked, and a nano pattern part (180) including a second opening part (181) randomly formed on a stacked surface of the substrate (111) stacked by the first electrode (112).

The substrate (111), the first electrode (112), the organic light emitting layer (113) and the second electrode (114) are stacked in that order. At this time, an additional layer may be interposed between each layer that performs an additional function. If the first electrode is an anode, the second electrode may be a cathode, and polarity of each electrode may be changed according to methods for manufacturing the organic electroluminescent device.

The nano pattern part (180) includes one or more second opening parts (181) randomly formed on the stacked surface of the substrate (111). The second opening part (181) may be a groove or a hole. Like the first opening part (181), if the second opening part is available, a convex part (182) expressing the second opening part is formed. A portion convexly formed by the second opening part becomes the convex part (182) while the second opening part (181) in turn corresponds to a concave part.

In the exemplary embodiment of the present disclosure, the nano pattern part corresponding to the nano embossing structure is directly formed on the surface of substrate. At this time, the second opening part of the nano pattern part is randomly formed on a stacked surface of the substrate. The stacked surface of the substrate is a surface facing a direction the first and second electrodes and organic light emitting layer are stacked.

The nano pattern part (180) may be generated by using a metal pattern formed by using the dewetting phenomenon. To be more specific, the dewetting phenomenon of a metal forming a metal layer is induced by stacking an organic layer and a metal layer in that order on the substrate and performing a heat treatment thereon. The metal pattern formed by the dewetting phenomenon is used as a mask for etching to etch the organic layer. Thereafter, if reactive ion etching is performed using fluorine and chloride compounds, the metal pattern and the organic pattern can be concurrently used as masks to form same patterns as those of metal pattern/organic pattern on the substrate itself. Solution including hydrofluoric acid may be used for wet etching during substrate etching. Meanwhile, the metal layer is removed along with the organic layer, such that there is no need of additionally removing the metal layer from the organic layer.

Referring to FIG. 10, an entire thickness of the organic electroluminescent device can be reduced by directly forming on the substrate a nano pattern part corresponding to the nano embossing structure.

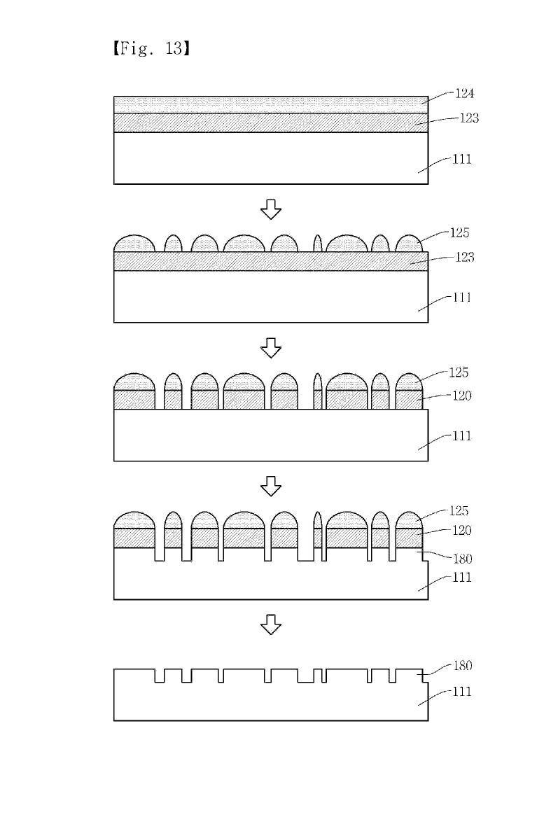

FIG. 11 is a schematic view illustrating an organic electroluminescent device according to still another exemplary embodiment of the present disclosure.

The organic electroluminescent device of FIG. 11 may include a light emitting part (110) in which a substrate (111), a first electrode (112), an organic light emitting layer (113) and a second electrode (114) are stacked, a nano structure (120) including a first opening part (121) randomly distributed between the substrate (111) and the first electrode (112), and a nano pattern part (180) including a second opening part (181) randomly formed on a stacked surface of the substrate (111) stacked by the first electrode (112). In the exemplary embodiment of the present disclosure, the nano pattern part (180) corresponding to the nano embossing structure is directly formed on the surface of substrate (111). Furthermore, a nano structure (120) is also included that is formed by the organic layer between the substrate (111) and the first electrode (112). Thus, the nano embossing structure is formed in a two-fold layer. At this time, the nano structure (120) may be stacked on the substrate, or on an additional layer that is additionally stacked on the substrate.

The second opening part (181) of the nano pattern part (180) and the first opening part (121) of the nano structure (120) are formed on the same position, or on different positions. As noted from the foregoing, the nano pattern part (180) includes the second opening part (181) and the convex part (182) formed by the second opening part. The nano structure (120) includes a first opening part (121) and a convex part (122) formed by the first opening part. Of course, the first and second opening parts (121, 181) are randomly distributed when viewed from a plane.

The nano pattern part (180) or the nano structure (120) may be generated by using a metal pattern formed by using the dewetting phenomenon. A manufacturing process of forming the first and second opening parts (121, 181) on the same position is as below:

The dewetting phenomenon of a metal forming a metal layer is induced by stacking an organic layer and a metal layer in that order on the substrate and performing a heat treatment thereon. The metal pattern formed by the dewetting phenomenon is used as a mask for etching to etch the organic layer. Thereafter, if reactive ion etching is performed using fluorine and chloride compounds, the metal pattern and the organic pattern can be concurrently used as masks to form the nano pattern part (180) having same patterns as those of metal pattern/organic pattern on the substrate itself. Thereafter, the metal pattern is removed to form the nano structure (120) stacked on the substrate. Solution including hydrofluoric acid may be used for wet etching during substrate etching.

The first opening part (121) may be a hole having a size configured to expose the substrate, or a groove having a size configured not to expose the substrate. In the exemplary embodiment of the present disclosure, the nano embossing structure is formed in a two layer structure to improve a light scattering effect.

The organic electroluminescent device disclosed by the aforementioned exemplary embodiments of the present disclosure is a structure manufactured using dewetting phenomenon and etching of metal. Thus, the organic electroluminescent device can be manufactured at a low cost with scattering efficiency remaining unchanged, in comparison with the organic electroluminescent device manufactured by electron beam lithography and nano imprinting methods where there is a deteriorated reliability, a difficulty in using on a large scale surface and a high manufacturing cost.

The nano structure (120) thus described is preferred to have a visible light absorptance less than 10%. This is because a high visible light absorptance in nano structure itself would reduce the light extraction efficiency.

Furthermore, the nano structure (120) may include at least any one of polyimide, epoxy, polycarbonate, PVC, PVP (Polyvinylpyrrolidone), polyethylene, polyacryl and perylene. At this time, the nano structure (120) includes a composite that contains materials such as polyimide, for example. A refractive index of the nano structure (120) needs to be same as that of the substrate or to be less than that of the substrate to improve the light extraction efficiency. Experimentally, the refractive index of the nano structure (120) is preferably in the range of 1.3˜1.5. Formation of a nano structure containing polyimide with a refractive index in the range of 1.3˜1.5 can harvest a nano structure with a desired refractive index and with a high yield.

width of the convex part (122) in the nano structure (120) may be the range of 100 nm˜1000 nm, and a gap between the convex parts (122) in the nano structure (120) may be in the range of 100 nm˜3000 nm. It was confirmed that set-up of width and gap of the convex part (122) in the nano structure thus described could harvest a reliable light extraction efficiency.

Likewise, width of the convex part (182) in the nano pattern part (180) may be the range of 100 nm˜1000 nm, and a gap between each convex part (182) may be in the range of 100 nm˜3000 nm.

Meanwhile, a planarizing layer (130) stacked to cover the nano structure (120) or the nano pattern part (180) may be additionally formed. The nano structure (120) or the nano pattern part (180) forms a nano embossing structure such that a cross-section of which has an embossed shape.

If the first electrode is stacked right under this state, the first electrode also has an embossed cross-section following the ruggedness. The embossed or rugged cross-section may be one of important factors resulting in a short circuit caused by the physical properties of the first electrode, the organic light emitting layer and the second electrode. Thus, there is a need of smoothing the surface of the first electrode. However, the first electrode using a transparent material like ITO cannot be smoothed if stacked on an embossed shape. Therefore, the planarizing layer (130) is stacked between the nano embossing structure and the first electrode.

The concave part in the nano embossing structure must be formed with a thick layer, and the convex part must be formed with a thin layer using the physical property of the planarizing layer (130). In order to satisfy the properties, the planarizing layer may include at least any one of inorganic matter, polymer and a composite of inorganic matter and polymer. Furthermore, the refractive index of the planarizing layer is preferably higher than that of the first electrode for a better light extraction. Thus, the inorganic matter, the polymer and the composite of inorganic matter and polymer forming the planarizing layer is preferred to have a refractive index in the range of 1.7˜2.5.

Although it was expected that the refractive index of the planarizing layer must be more than 1.9, in view of the fact that the anode (ITO) which is a first electrode has a refractive index in the range of 1.9˜2.0, it was confirmed that the light extraction efficiency was high with a refractive index of 1.7 as a result of the experiment. It is estimated that ruggedness or embossed surface, instead of ideally smoothness, of the planarizing layer has a scattering effect. It was confirmed that although the refractive index of the planarizing layer is higher than that of the nano structure or the nano pattern part, the stack of the planarizing layer on the nano structure or the nano pattern part directly affects the light scattering effect, whereby the degree of the light extraction efficiency being decreased by the difference of refractive index can be reduced.

The inorganic matter used for the planarizing layer includes at least any one of TiO2, TiO2-SiO2, ZrO2, ZnS, SnO2 and In2O3, and the polymer includes at least any one of polyvinyl, phenol resin, epoxy resin, polyimide resin, polystyrene resin, polycarbonate resin, polyethylene resin, PMMA resin, polypropylene resin and silicone resin.

Meanwhile, an external light extraction part may be formed at a surface opposite to the stacked surface of the substrate (111) stacked by the first electrode (112). The external light extraction part may be an MLA (Multi-lens Array) layer, an external light scattering layer and antireflective film, for example, and may be formed in a micro embossing pattern.

A detailed methods of forming the MLA layer includes a method in which an MLA is formed on a film having a refractive index as that of the substrate, which is then attached to an external surface of the substrate, and a method in which an external surface of the substrate is patterned, etched and directly engraved with the MLA shape.

The formation of an embossed pattern having an adequate height and width on the external surface of the substrate can harvest an effect similar to that of MLA formation. The shape of the embossed pattern may include a pyramid shape, a pillar shape, a moire shape and other rugged uneven irregular shapes. A detailed formation method of embossed pattern may be to form and attach a film as in the MLA formation, or to etch a substrate into which the embossed pattern is directly engraved.

Formation of light scattering layer on the external surface of the substrate prevents light incident on an interface between the substrate and the outside air from being totally reflected and allows the light to be scattered every which way, whereby light emitted to outside can be increased. At this time, a light scattering layer must be mixed with a material of high refractive index and a material of low refractive index, where it is preferable that a material of high refractive index form a base while a material of low refractive index form scattering particles. It is preferable that a refractive index of base material be similar to or a little higher than that of the substrate.

The antireflective or anti-reflection (AR) coating is a type of optical coating applied to the surface of lenses and other optical devices to reduce reflection. This improves the efficiency of the system since less light is lost. Antireflective coating may include a method of using a single layer film and a method of using multiple thin films, both of which may further enhance the light extraction efficiency if applied to an external surface of a substrate of the organic electroluminescent device according to the present disclosure.

That is, simultaneous use of the internal light extraction method using the nano structure or nano pattern part, and the external light extraction method using the MLA and the like can improve the light extraction efficiency of the organic electroluminescent device.

The method for manufacturing the organic electroluminescent device stacked with the substrate (111), the first electrode (112), the organic light emitting layer (113) and the second electrode (114) is to form the nano structure (120) or the nano pattern part (180) between the substrate (111) and the first electrode (112) using a metal film formed by dewetting phenomenon as a mask.

Now, a method for manufacturing the organic electroluminescent device will be described in detail.

FIG. 12 is a schematic view illustrating a process of manufacturing an organic electroluminescent device according to the present disclosure.

First, an organic layer (123) is coated on a substrate (111). The organic layer may include at least any one of polyimide, epoxy, polycarbonate, PVC, PVP (Polyvinylpyrrolidone), polyethylene, polyacryl and perylene. In view of the fact that a refractive index of a transparent substrate is approximately 1.5, a refractive index of the organic layer is preferably in a lower range of 1.3˜1.5.

A metal layer (124) is deposited on the organic layer (123). A pattern (metal pattern, 125) is harvested in which a first part (convex part of FIG. 9, 172) of the substrate (111) being heated and a metal forming a metal film (124) being collected by dewetting phenomenon, and a second part (opening part of FIG. 9, 171) of the organic layer (123) being exposed are randomly mixed. The reason of heating the metal film (124) is to enhance the purpose and convenience for manufacturing the organic electroluminescent device, and a substrate stacked with the organic layer and the metal film is directly heated.

The organic layer (123) of the second part is etched to expose the substrate (111). At this time, a portion of the substrate exposed to the outside is same as the second part.

The metal film (124) is removed. At this time, the removed metal film is substantially the metal pattern (125). The remaining organic layer (123) formed by removing the metal layer becomes the nano structure (120).

According to the method thus described, an organic electroluminescent device of FIG. 8 is manufactured. There is a method for manufacturing an organic electroluminescent device by allowing a separately provided organic layer to become a nano structure. According to this method, a refractive index, a height, a width and a gap of the nano structure can be adjusted as desired. Therefore, a refractive index, a height, a width and a gap necessary for optimal light extraction can be easily set up.

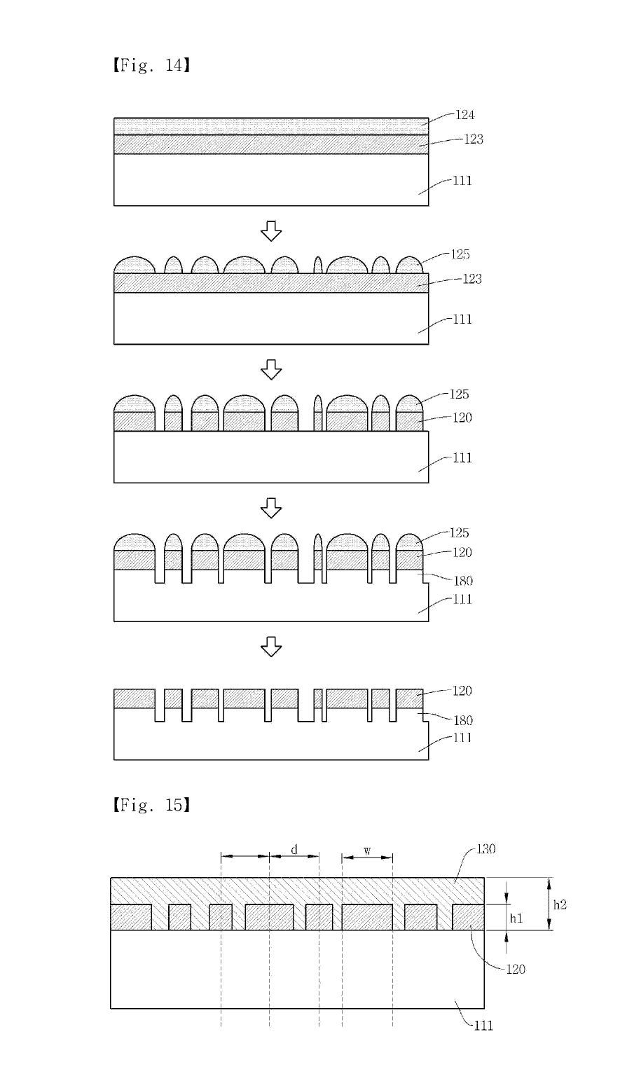

FIG. 13 is a schematic view illustrating another process of manufacturing an organic electroluminescent device according to the present disclosure.

First, an organic layer (123) is coated on a substrate (111). At this time the organic layer may include at least any one of polyimide, epoxy, polycarbonate, PVC, PVP (Polyvinylpyrrolidone), polyethylene, polyacryl and perylene, each having a refractive index in the range of 1.3˜1.5.

A metal layer (124) is deposited on the organic layer (123). A pattern is harvested in which a first part in which the substrate (111) is heated and a metal forming a metal film (124) is collected by dewetting phenomenon, and a second part in which the organic layer (123) is exposed are randomly mixed.

The organic layer (123) of the second part is etched to expose the substrate (111). At this time, a nano pattern part (180) is formed on the substrate itself in the course of the etching.

The organic layer (123) is removed. The removal of the organic layer (123) spontaneously removes the metal film (124) from the substrate because the metal film is stacked on the organic layer (123). Only the substrate formed with the nano pattern part remains after this process. An organic electroluminescent device according to FIG. 10 is manufactured by the manufacturing method thus described.

FIG. 14 is a schematic view illustrating still another process of manufacturing an organic electroluminescent device according to the present disclosure.

First, an organic layer (123) is coated on a substrate (111). At this time the organic layer may include at least any one of polyimide, epoxy, polycarbonate, PVC, PVP (Polyvinylpyrrolidone), polyethylene, polyacryl and perylene, each having a refractive index in the range of 1.3˜1.5.

A metal layer (124) is deposited on the organic layer (123). A pattern (metal pattern, 125) is harvested in which a first part in which the substrate (111) is heated and a metal forming a metal film (124) is collected by dewetting phenomenon, and a second part in which the organic layer (123) is exposed, are randomly mixed.

Etching of the second part allows the substrate (111) to be exposed. Etching of the organic layer (123) at the second part allows the organic layer (123) to become the nano structure (120).

The exposed portion of the substrate (111) is etched, whereby a nano pattern part is formed on the substrate itself. The metal film (124) is removed, where the metal pattern (125) is substantially removed, and thereafter, a nano structure (120) formed with the organic layer (123), and the substrate (111) formed with the nano pattern part (180) remain. Based on the above manufacturing method, an organic electroluminescent device of FIG. 11 is manufactured.

A temperature heating the substrate for realizing the dewetting phenomenon in each manufacturing methods thus described may be in the range of 200° C.˜400° C. At this time, the temperature is a temperature of an ambience in which the substrate is heated, not the temperature of the substrate itself.

width of the first portion in the metal pattern (125) may be in the range of 100 nm ˜1000 nm, and a distance to the first portion may be in the range of 100 nm ˜3000 nm.

The first part of the metal pattern is a portion corresponding to the convex part of the nano structure or the nano pattern part. Thus, a width and distance of the metal pattern is the width and distance of the convex part of the nano structure or the nano pattern part. The width of the first part is same as a width ‘w’ of the convex part of the nano structure (120) or the width ‘w’ of the convex part of the nano pattern part in FIG. 15, for example. Furthermore, the distance of the first part is same as a distance ‘d’ of the convex part of the nano structure/nano pattern part.

The metal film (124) may include at least any one of Ag, Au, Cu, Pt, Ni, Cr, Pd, Mg, Pb and Mo. The metal film including these materials is adequate to the heating temperature necessary for realizing the dewetting phenomenon.

The thickness of the metal film (124) may be in the range of 5 nm˜100 nm. The thickness can be set up within these ranges with reference to the shape of the metal pattern to be formed by the dewetting phenomenon. The shape of the metal pattern may be the one as water bubble as described before.

The thickness of the organic layer may be in the range of 50 nm˜1000 nm. The thickness of the organic layer becomes the thickness of the nano structure. Thus, an adequate thickness may be selected in consideration of a wavelength area of the visible light to be extracted from the organic electroluminescent device.

In a case the organic layer (123) is used for a simple mask purpose as in the manufacturing method of FIG. 13, the thickness of the organic layer is preferably as thin as possible within the relevant range in consideration of manufacturing cost. The thickness of the organic layer in FIG. 15 is same as a stacked height ‘h₁’ of the nano structure (120), for example.

Meanwhile, in order to prevent occurrence of short-circuit after the manufacturing methods of FIGS. 12 to 14 are finished to form the nano structure or the nano pattern part, the planarizing layer may be stacked on the nano structure or the nano pattern part.

At this time the planarizing layer preferably has a thickness in the range of 100 nm ˜2000 nm, a visible light absorptance of less than 10% and a surface roughness Ra of less than 10 nm. The materials that satisfy these conditions are as mentioned in the foregoing. The thickness of the planarizing layer in FIG. 15 is same as a height “h₂’ from a bottom portion of the convex part of the nano structure to an opposite surface of the planarizing layer, for example.

Furthermore, a process of additionally forming on the substrate (111) at least anyone of an MLA (Micro-lens Array) layer, a micro embossed pattern layer, a light scattering layer and an antireflective coating layer may be included.

In forming an external light extraction part on the substrate (111), the external light extraction part is preferably formed on a surface opposite to a direction where the first electrode, the organic light emitting layer and the second electrode are stacked on the substrate.

The previous description of the present invention is provided to enable any person skilled in the art to make or use the invention. Various modifications to the invention will be readily apparent to those skilled in the art, and the generic principles defined herein may be applied to other variations without departing from the spirit or scope of the invention. Thus, the invention is not intended to limit the examples described herein, but is to be accorded the widest scope consistent with the principles and novel features disclosed herein.

As apparent from the foregoing, the organic electroluminescent device and the method for manufacturing thereof according to the present disclosure have an industrial applicability in that the device includes a nano embossed structure randomly interposed between a substrate and a first electrode stacked on the substrate and a nano pattern part, whereby a light extraction can be improved by restricting a reflective light from an interface between the substrate and the first electrode.

Another industrial applicability is that the nano structure is randomly generated by using dewetting phenomenon of metal to simplify a manufacturing process.

Still another industrial applicability is that a refractive index, height, width gap can be adjusted as desired if a nano structure of organic layer is applied, thereby enabling to obtain a reliable light extraction, whereby an organic electroluminescent device improved of light extraction efficiency can be provided with a less manufacturing cost.

What is claimed is:

1. An organic electroluminescent device, the device comprising: a light emitting part in which a substrate, a first electrode, an organic light emitting layer and a second electrode are stacked; and a nano structure including a first opening part randomly distributed between the substrate and the first electrode, wherein the nano structure includes at least any one of polyimide, epoxy, polycarbonate, PVC, PVP, polyethylene, polyacryl and perylene, each having a refractive index in the range of 1.3˜1.5.

2. An organic electroluminescent device, the device comprising: a light emitting part in which a substrate, a first electrode, an organic light emitting layer and a second electrode are stacked; a nano structure including a first opening part randomly distributed between the substrate and the first electrode; and a nano pattern part including a second opening part randomly formed on a stacked surface of the substrate on which the first electrode is stacked.

3. The device of claim 2, wherein the nano structure is less than 10% in visible light absorptance.

4. The device of claim 2, wherein the nano structure includes at least any one of polyimide, epoxy, polycarbonate, PVC, PVP, polyethylene, polyacryl and perylene, each having a refractive index in the range of 1.3˜1.5.

5. The device of claim 2, wherein width of the nano structure is in the range of 100 nm˜1000 nm, and a gap between each nano structure is in the range of 100 nm˜3000 nm.

6. The device of claim 2, wherein width of a convex part formed at the nano pattern part is in the range of 100 nm˜1000 nm, and a gap between each convex part is in the range of 100 nm˜3000 nm.

7. The device of claim 2, further comprising a planarizing layer stacked to cover the nano structure, wherein the planarizing layer includes at least one of inorganic matter, polymer and a composite of the inorganic matter and the polymer, wherein the inorganic matter includes at least any one of TiO2, TiO02-SiO2, ZrO2, ZnS, SnO2 and In2O3, and wherein the polymer includes at least any one of polyvinyl, phenol resin, epoxy resin, polyimide resin, polystyrene resin, polycarbonate resin, polyethylene resin, PMMA resin, polypropylene resin and silicone resin.

8. The device of claim 2, wherein an external light extraction part is formed at a surface opposite to the stacked surface of the substrate on which the first electrode is stacked.

9. A method for manufacturing an organic electroluminescent device, the method comprising: forming a nano structure or a nano pattern part between a substrate and a first electrode by masking a metal film formed by dewetting in an organic electroluminescent device on which a substrate, a first electrode, an organic light emitting layer and a second electrode.

10. A method for manufacturing an organic electroluminescent device, the method comprising: coating on a substrate an organic layer including at least any one of polyimide, epoxy, polycarbonate, PVC, PVP (Polyvinylpyrrolidone), polyethylene, polyacryl and perylene, each having a refractive index in the range of 1.3˜1.5; depositing a metal film on the organic layer; obtaining a pattern in which a first portion, where a metal formed with the metal film by heating the substrate is collected by dewetting, and a second portion exposed by the organic layer are mixed in a randomly shape; exposing the substrate by etching the second portion; and removing the metal film.

11. The method of claim 10, wherein a temperature heating the substrate is in the range of 200° C.˜400° C.

12. The method of claim 10, wherein width of the first portion is in the range of 100 nm˜1000 nm, and a distance to the first portion is in the range of 100 nm˜3000 nm.

13. The method of claim 10, wherein the metal film includes at least any one of Ag, Au, Cu, Pt, Ni, Cr, Pd, Mg, Pb and Mo.

14. The method of claim 10, wherein thickness of the metal film is in the range of 5 nm˜100 nm.

15. The method of claim 10, wherein thickness of the organic layer is in the range of 50 nm˜1000 nm.

16. The method of claim 10, further comprising forming a planarizing layer having a thickness in the range of 100 nm˜2000 nm, a visible light absorptance of less than 10% and a surface roughness Ra of less than 10 nm.

17. The method of claim 10, further comprising forming on the substrate at least any one of an MLA (Micro-lens Array) layer, a fine embossed pattern layer, a light scattering layer and an antireflective coating layer.
